(19) United States
(12) Patent Application Publication
(10) Pub. No.: US 2005/0223985 A1
(43) Pub. Date: Oct. 13, 2005

(54) Deposition apparatuses, methods of assessing the temperature of semiconductor wafer substrates within deposition apparatuses, and methods for deposition of epitaxial semiconductive material

(76) Inventors: Eric R. Blomiley, Boise, ID (US); Nirmal Ramaswamy, Boise, ID (US); Ross S. Dando, Nampa, ID (US); Joel A. Drewes, Boise, ID (US); Alan B. Colwell, Boise, ID (US); Eduardo A. Tovar, Caldwell, ID (US)

Correspondence Address: WELLS ST. JOHN P.S., 601 W. FIRST AVENUE, SUITE 1300, SPOKANE, WA, 99201, US

(21) Appl. No.: 10/822,208

(22) Filed: Apr. 8, 2004

(51) Int. Cl. C23C 16/00; H01L 21/66

(52) U.S. Cl. 118/715; 438/14; 118/725; 118/666

(57) ABSTRACT

The invention includes deposition apparatuses configured to monitor the temperature of a semiconductor wafer substrate by utilizing conduits which channel radiation from the substrate to a detector/signal processor system. In particular aspects, the temperature of the substrate can be measured while the substrate is spinning within a reaction chamber. The invention also includes deposition apparatuses in which flow of mixed gases is controlled by mass flow controllers provided downstream of the location where the gases are mixed and/or where flow of gases is measured with mass flow measurement devices provided downstream of the location where the gases are mixed. Additionally, the invention encompasses deposition apparatuses in which mass flow controllers and/or mass flow measurement devices are provided upstream of a header which splits a source gas into multiple paths directed toward multiple different reaction chambers.

### TECHNICAL FIELD

The invention pertains to deposition apparatuses, and in particular aspects pertains to apparatuses configured for deposition of epitaxial semiconductive material. The invention also pertains to methods of depositing epitaxial semiconductive material, and methods of assessing the temperature of a semiconductor wafer substrate within a deposition apparatus.

### BACKGROUND OF THE INVENTION

Integrated circuitry fabrication includes deposition of materials and layers over semiconductor wafer substrates. One or more substrates are received within a deposition chamber within which deposition typically occurs. One or more precursors or substances are caused to flow to a substrate, typically as a vapor, to effect deposition of a layer over the substrate. A single substrate is typically positioned or supported for deposition by a susceptor. In the context of this document, a “susceptor” is any device which holds or supports at least one wafer within a chamber or environment for deposition. Deposition may occur by chemical vapor deposition, atomic layer deposition and/or by other means.

FIGS. 1 and 2 diagrammatically depict a prior art susceptor 12, and various issues associated therewith. Susceptor 12 receives a semiconductor wafer substrate 14 (shown in dashed-line view in FIG. 2) for deposition. Substrate 14 is received within a pocket or recess 16 of the susceptor to elevationally and laterally retain substrate 14 in the desired position.

A particular exemplary system is a lamp heated, thermal deposition system having front and back side radiant heating of the substrate and susceptor for attaining and maintaining desired temperature during deposition. FIG. 2 depicts a thermal deposition system having at least two radiant heating sources for each side of susceptor 12. Depicted are front side and back side peripheral radiation emitting sources 18 and 20, respectively, and front side and back side radially inner radiation emitting sources 22 and 24, respectively. Incident radiation from sources 18, 20, 22 and 24 overlaps on the susceptor and substrate, creating overlap areas 25. Such can cause an annular region of the substrate corresponding in position to overlap areas 25 to be hotter than other areas of the substrate not so overlapped. Further, the center and periphery of the substrate can be cooler than even the substrate area which is not overlapped due to less than complete or even exposure to the incident radiation.

The susceptor is typically caused to rotate during deposition, with deposition precursor gas flows occurring across the wafer substrate. An H₂ gas curtain (not shown) will typically be provided within the chamber proximate a slit valve (not shown) through which the substrate is moved into and out of the chamber. A preheat ring (not shown) is typically received about the susceptor, and provides another heat source which heats the gas flowing within the deposition chamber to the wafer. In spite of the preheat ring, the regions of the substrate proximate where gas flows to the substrate can be cooler than other regions of the substrate.

Robotic arms (not shown) are typically used to position substrate 14 within recess 16. Such positioning of substrate 14 does not always result in the substrate being positioned entirely within susceptor recess 16. Further, gas flow might dislodge the wafer such that it is received both within and without recess 16. Such can further result in temperature variation across the substrate and, regardless, result in less controlled or uniform deposition over substrate 14.

A portion of an exemplary deposition apparatus 30 which can be utilized in accordance with prior art processing is described with reference to FIG. 3. Apparatus 30 comprises a reaction chamber 32 within which is provided the susceptor 12 and substrate 14 described previously. Susceptor 12 is diagrammatically shown supported by a base 34. It is to be understood that the susceptor would typically be supported in a manner such that the susceptor can be rotated within the chamber during a deposition process.

A plurality of inlets I₁, I₂ and I₃ are shown extending into the chamber, and an outlet, O, is also shown extending into the chamber. Although three inlets and one outlet are shown, it is to be understood that there can be other numbers of inlets and outlets provided. The inlets and outlet would typically have valves (not shown) provided across them to regulate flow into and out of chamber 32.

An exemplary use for apparatus 30 is chemical vapor deposition, and specifically deposition of epitaxial semiconductive materials, such as, for example semiconductive materials comprising, consisting essentially of, or consisting of one or both of silicon and germanium, either in doped or undoped form. In such operations, several precursors are mixed upstream of chamber 32. The mixed precursors are then flowed into the chamber through inlets I₁, I₂ and I₃ whereupon the precursors form a deposit over substrate 14. The mixed precursors are flowed through multiple inlets in an effort to increase the homogeneity of a deposition operation relative to the homogeneity which will result if fewer inlets are used. The various inlets can be utilized to direct gas flow to various portions of wafer substrate 14. For instance, one or more of the inlets can direct gas flow to peripheral regions of the wafer while one or more other inlets direct gas flow to central regions of the wafer. In spite of the utilization of numerous inlets, problems with homogeneity can still result. The problems may be due to, for example, substrate 14 not being uniformly heated during the deposition process, or other parameters associated with reaction chamber 32 not being adequately controlled.

FIG. 4 schematically illustrates precursor mixing associated with apparatus 30. Specifically, three sources of gases are provided, with the sources being labeled S₁, S₂ and S₃. The gases in sources S₁, S₂ and S₃ can be referred to as a first gas, second gas and third gas, respectively. In aspects in which apparatus 30 is utilized for deposition of an epitaxial semiconductive material, one of the gases can be dichlorosilane, another can be H₂, and another can be a suitable dopant or dopant precursor. Exemplary gases which can be flowed as dopants and dopant precursors include, for example, PH₃, B₂H₆, BCI₃, AsH₃, etc.

The apparatus 30 comprises a flow line system 36 configured to direct gases from sources S₁, S₂ and S₃ to a location 38 where the gases are combined to form a mixture. The flow line system 36 also comprises a splitter 40 through which the gas mixture is split into three separate flow paths. The flow paths lead to the inlets I₁, I₂ and I₃, respectively.

A series of controllers C₁, C₂ and C₃ are within flow line system 36 and utilized for controlling flow of the first, second and third gases, respectively, to the location 38 where the gases are mixed. The controllers can be any suitable mass flow controllers, including, for example, analog flow controllers. Notably, no controllers are provided after mixture of the gases at location 38. Rather, the mixed gases are simply flowed through splitter 40 and into chamber 32, with the assumption being that appropriate mixtures will be flowed into inlets I₁, I₂ and I₃ without additional regulation of flow of material downstream of location 38 within flow system 36. It is noted that there may be simple valves downstream of location 38 within the FIG. 4 system, with such valves being configured for turning flow either fully on or fully off, but simple valves utilized to turn flow fully on or fully off are not to be understood to be the same as mass flow controllers for purposes of understanding this disclosure and the claims that follow. Rather, mass flow controllers are known to persons of ordinary skill in the art to be designed for regulating flow at levels extending from a fully on position to a fully off position, which can include turning the flow fully on or fully off, but which is not limited to turning the flow fully on or fully off, in contrast to simple valves. Simple valves can be partially open, which is in a sense controlling flow at a position between fully on and fully off, but this is not the same level of control as is provided by an actual mass flow controller. Mass flow controllers can be either digital or analog, with analog mass flow controllers being commonly utilized. Exemplary mass flow controllers are available from MKS, STEC, Hitachi, Aera, etc., and such can control gas flow from about 5 standard cubic centimeters per minute (sccm) to about 100,000 sccm, to within about 2%.

Although apparatus 30 is shown to comprise only one chamber in the simplistic diagrams of FIGS. 3 and 4, it is to be understood that apparatuses commonly comprise multiple reaction chambers which are together utilized to increase throughput of semiconductor wafers through the apparatuses. FIG. 5 schematically illustrates additional aspects of the apparatus 30 of FIGS. 3 and 4, where such apparatus is shown to comprise three reaction chambers, 32, 42 and 52. The sources S₁, S₂ and S₃ described with reference to FIG. 4 are utilized, and gases are flowed through the controllers C₁, C₂ and C₃, as discussed above, to a location 38 where the gases from the sources are mixed. The mixture is flowed from location 38 to a splitter 44 which splits the gases into flow paths 46, 48 and 50 extending into the chambers 32, 42 and 52, respectively. The flow path 46 leads to the splitter 40 discussed previously which splits the combined gases amongst the inlets I₁, I₂ and I₃ of the FIG. 3 reaction chamber. Similarly, flow paths 48 and 50 lead to splitters 54 and 56, respectively. The splitter 54 splits the gases amongst inlets I₄, I₅ and I₆, leading to chamber 42; and the splitter 56 splits the gases amongst inlets I₇, I₈ and I₉ leading to chamber 52.

FIG. 5 shows that flow controllers are provided only upstream of the location 38 where the gases are mixed, and not downstream of such location in the prior art apparatus.

A continuing goal during deposition of materials over semiconductor wafer substrates is to attain layers of deposited material having uniform thickness and uniform composition. It would be desirable to develop methodologies and apparatuses which can improve deposition processes to attain more uniform layer thickness and/or better homogeneity of layer composition than is attained with existing processes. Although the invention was motivated from the perspective of improving deposition processes, and specifically was motivated in conjunction with the reactor and susceptor designs described above, the invention is not to be limited to such aspects. Rather, the invention is only limited by the accompanying claims as literally worded, without interpretive or other limiting reference to the specification and drawings, and in accordance with the doctrine of equivalents.

### SUMMARY OF THE INVENTION

In one aspect, the invention encompasses a deposition apparatus. The apparatus includes a substrate susceptor for receiving a semiconductor wafer substrate, and one or more heating sources for providing thermal energy to the substrate. The apparatus further includes a radiation detector, and a radiation conduit proximate a region of the semiconductor substrate and configured to channel radiation from the region of the substrate to the detector. The detector is configured to receive the radiation from the conduit and output one or more data signals in response to the radiation. The apparatus further includes a signal processor in data communication with the detector and configured to process at least one data signal from the detector and to correlate the data signal with the temperature of the region of the substrate.

In one aspect, the invention encompasses a method of assessing the temperature of a semiconductor wafer substrate. A deposition apparatus is provided which includes a susceptor for receiving a semiconductor wafer substrate, a radiation detector, and a plurality of radiation conduits proximate the substrate as it is received in the susceptor. The apparatus further includes a signal processor in data communication with the detector. The method includes defining a plurality of annular regions extending radially inwardly of one another within the semiconductor wafer substrate. The substrate and susceptor are spun, and radiation is channeled from the annular regions of the substrate through the radiation conduits to the detector as the substrate and susceptor are spinning. The detector sends data signals to the signal processor, and such signals are processed to assess the temperatures of the annular regions of the substrate.

In one aspect, the invention encompasses an apparatus configured for deposition of epitaxial semiconductor material. Such apparatus includes a plurality of gas sources, and a location downstream of the gas sources where the gases are mixed. The apparatus further includes mass flow controllers and/or mass flow measuring devices provided downstream of the location where the gases are mixed, with the mass flow controllers being other than simple valves.

In one aspect, the invention encompasses a deposition apparatus in which one or more mass flow controllers and/or one or more mass flow measurement devices are provided upstream of a header which splits a source gas into multiple paths directed toward multiple different reaction chambers.

### BRIEF DESCRIPTION OF THE DRAWINGS

Preferred embodiments of the invention are described below with reference to the following accompanying drawings.

FIG. 1 is a top view of a prior art susceptor.

FIG. 2 is a cross-section of the FIG. 1 susceptor taken through the line 2-2 of FIG. 1, and shown in combination with a semiconductor wafer substrate and heating sources.

FIG. 3 is a diagrammatic, cross-sectional view of a prior art apparatus which can be utilized for deposition of materials over semiconductor substrates.

FIG. 4 is a schematic view of the apparatus of FIG. 3 illustrating a flow system that can be utilized for flowing mixed gases to a reaction chamber of the apparatus.

FIG. 5 is a schematic view of the prior art apparatus of FIGS. 3 and 4 illustrating additional aspects of the flow system that can be utilized for flowing gases through the apparatus.

FIG. 6 is a diagrammatic, cross-sectional view of an assembly that can be incorporated into a reaction chamber in accordance with an aspect of the present invention for monitoring a temperature of a semiconductor wafer process in the chamber.

FIG. 7 is a top-down view of a section of the apparatus of FIG. 6 along the line of 7-7 of FIG. 6.

FIG. 8 is a top-down view of a section of the apparatus of FIG. 6 along the line of 8-8 of FIG. 6.

FIG. 9 is a top-down view of a portion of the FIG. 6 apparatus along the line 9-9 of FIG. 6.

FIG. 10 is a top-down view of a portion of the FIG. 6 apparatus along the line of 8-8 illustrating an embodiment of the invention alternative to that of FIG. 8.

FIG. 11 is a diagrammatic view of a connection that can be utilized for connecting a rotating portion of the FIG. 6 apparatus to a stationary portion of the apparatus.

FIG. 12 is a cross-sectional side view along the line 12-12 of FIG. 11.

FIG. 13 is a diagrammatic view of another connection that can be utilized for connecting a rotating portion of the FIG. 6 apparatus to a stationary portion of the apparatus.

FIG. 14 is a cross-sectional side view along the line 14-14 of FIG. 13.

FIG. 15 is a schematic view of a gas flow system which can be incorporated into an apparatus of the present invention.

FIG. 16 is a schematic view of another gas flow system which can be incorporated into an apparatus of the present invention.

FIG. 17 is a schematic view of yet another gas flow system which can be incorporated into an apparatus of the present invention.

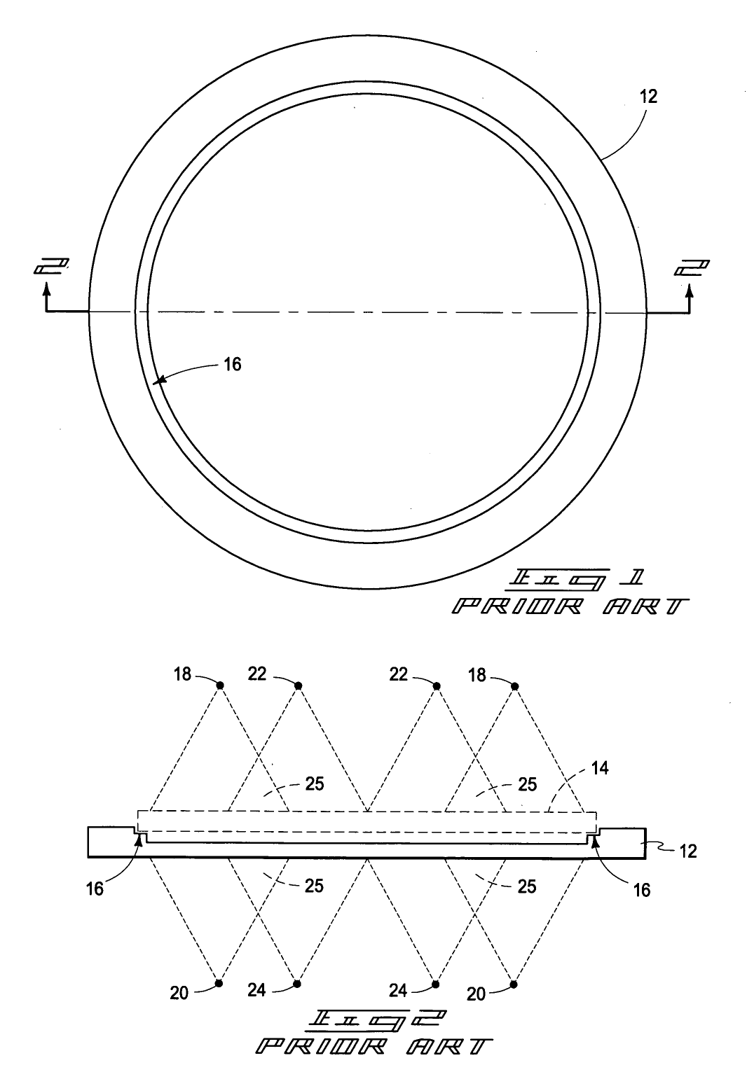

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

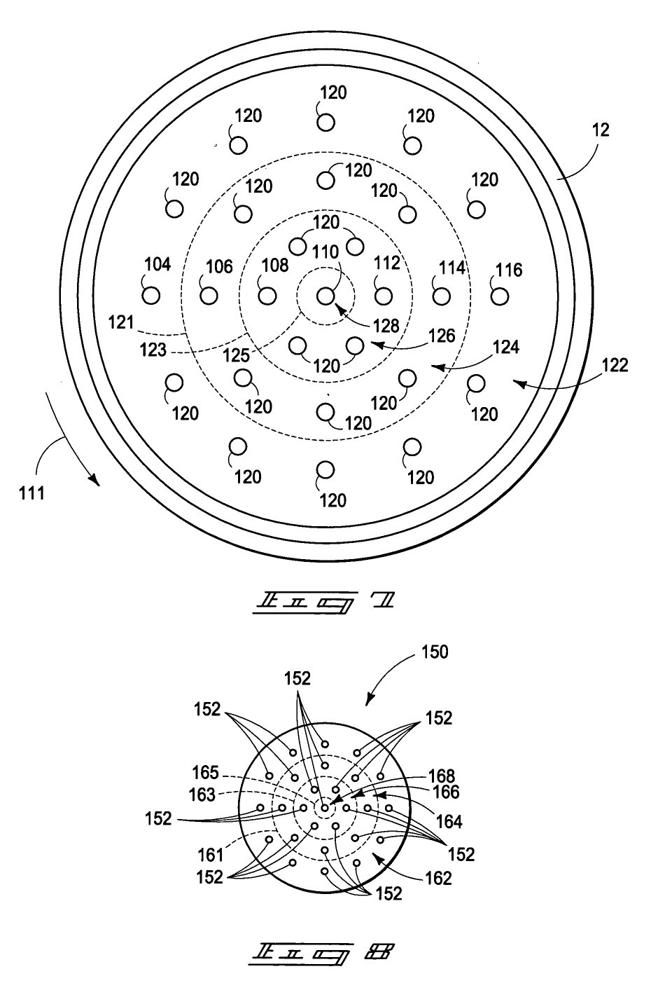

One aspect of the invention is a recognition that it would be desirable to develop improved methods for monitoring the temperature across a semiconductor wafer during a deposition process. The improved methods can be utilized for, for example, continuously assessing the uniformity of the temperature across the semiconductor wafer surface. FIGS. 6-14 illustrate exemplary apparatuses which can be formed in accordance with aspects of the present invention for monitoring the temperature across a semiconductor substrate during a deposition process.

Referring initially to FIGS. 6-9, a susceptor 12 is illustrated incorporated into exemplary apparatus 100. A wafer 14 is shown received by the susceptor 12, and a gap, or trough, 15 is beneath the wafer. A housing 102 extends downwardly from receptor 12, and in typical aspects would be rotated with susceptor 12 during a deposition process.

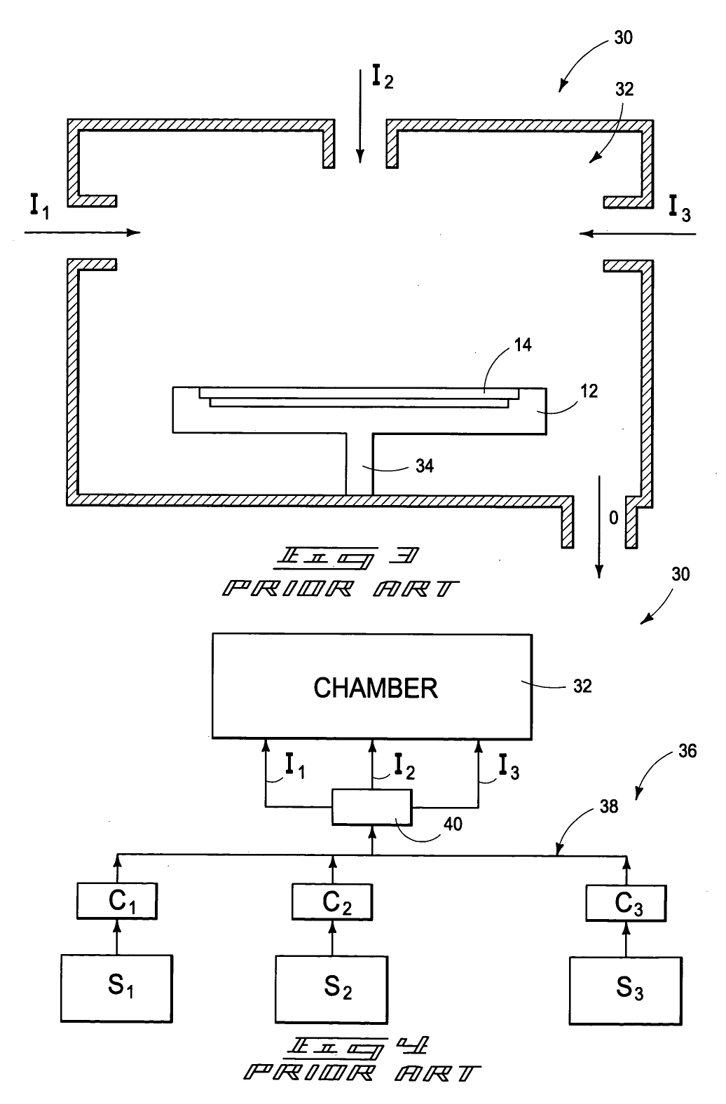

In operation, one or more heating sources (such as one or more of the sources 18, 20, 22 and 24 discussed previously with reference to FIG. 2) would be utilized for providing thermal energy to substrate 14 during a deposition process. The heating sources are not shown in FIG. 6 in order to simplify the drawing.

A plurality of radiation conduits 104, 106, 108, 110, 112, 114 and 116 are shown in FIG. 6, and FIG. 7 shows that the conduits are part of an array of conduits arranged in concentric rings. The other conduits of the array are identified by the general label 120 in FIG. 7. The concentric rings are labeled as 122, 124, 126 and 128 in FIG. 7, and are diagrammatically bounded by dashed lines 121, 123 and 125. The susceptor would generally be spun during a deposition process, and such spinning is represented by the arrow 111 in FIG. 7.

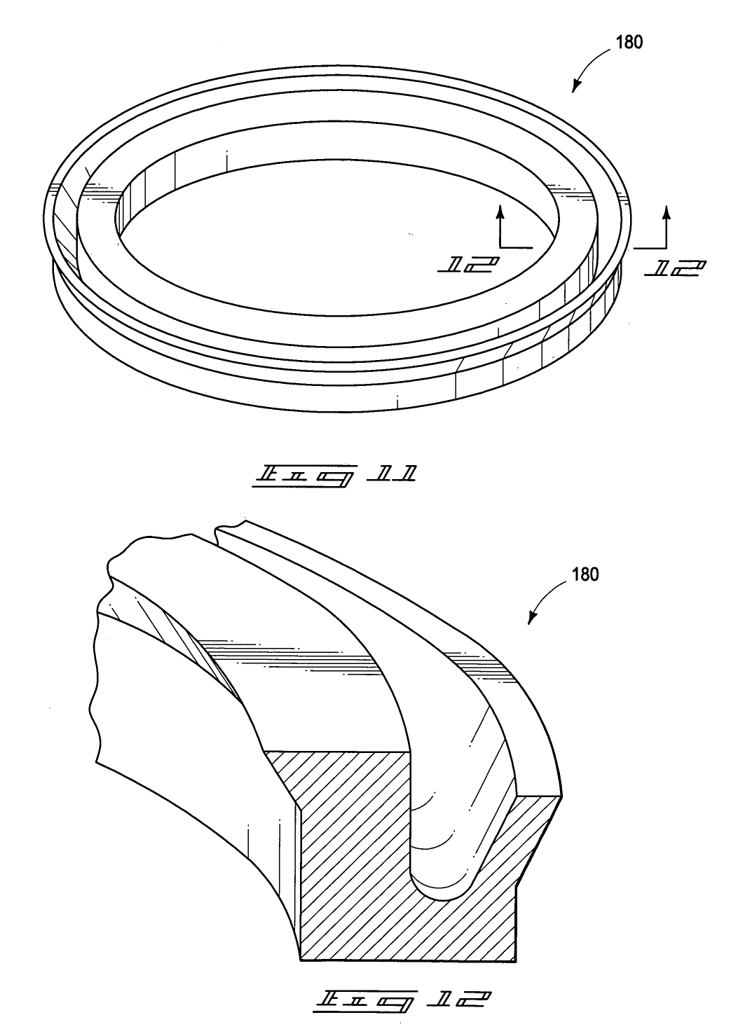

FIG. 9 shows that semiconductor wafer 14 is generally a substantially circular semiconductor substrate (the wafer may be nearly exactly circular, or may have a flat along one side as is to known to persons of ordinary skill in the art), and the substrate can be considered to comprise a plurality of annular regions 132, 134, 136 and 138 extending radially inwardly of one another, with the shown regions being separated by dashed lines 131,133 and 135 representing boundaries between the defined regions.

The defined annular regions 132, 134, 136 and 138 of substrate 14 are in one-to-one correspondence with the annular regions 122, 124, 126 and 128 of the plurality of radiation conduits, as can be seen in FIG. 6. As will become more clear in the discussion that follows, each of the annular rings of the substrate constitutes a separate region for which a temperature is monitored in accordance with the aspects of the invention of FIGS. 6-14. Accordingly, the temperature of ring (or annulus) 132 of substrate 14 is separately monitored from the temperature of ring 134, which in turn is separately monitored from the temperature of ring 136, which in turn is separately monitored from the temperature of ring 138. The monitoring of the temperatures of the annular rings enables the uniformity of temperature across substrate 14 to be monitored during a deposition reaction. In particular aspects of the invention, feedback from the temperature monitoring can be utilized to control thermal energy sources to maintain temperature uniformity across wafer 14 within desired tolerances during a deposition process. Although the monitored regions of the substrate are shown and described as rings in the specific aspect of the invention described herein, it is to be understood that the monitored regions can have other shapes in other aspects of the invention.

In the shown aspect of the invention, a plurality of radiation conduits are within the regions 122, 124 and 126 of the conduit array of FIG. 7, and only one radiation conduit is within the region 128 of the conduit array. Accordingly, the plurality of radiation conduits are associated with each of the regions 132, 134 and 136 of the substrate 14 of FIG. 9, and only one radiation conduit is associated with the region 138. It is to be understood that the invention encompasses other aspects wherein a plurality of conduits are associated with region 128 and/or where only one conduit is associated with one or more of the regions 122, 124 and 126. Generally, at least one radiation conduit will be associated with each of the annular regions defined within substrate 14.

Substrate 14 can be considered to comprise a front side (the upper surface of substrate 14 in the view of FIG. 6) upon which deposition of material is to occur, and a back side in opposing relation to the front side and facing susceptor 12. The radiation conduits 104, 106, 108, 110, 112, 114 and 116 are shown in FIG. 6 to extend to proximate the back side surface of substrate 14, and are shown to extend through susceptor 12. The radiation conduits can comprise any structure which can channel radiation from regions of substrate 14 to a detector. The radiation channeled from substrate 14 will be radiation indicative of the temperature of substrate 14, and accordingly will typically be black-body radiation. The conduits will typically be fibers appropriately configured to channel black-body radiation, and can be, in some aspects, fiber optics suitable for channeling infrared radiation. In alternative, or additional aspects, the conduits can include fiber optics suitable for channeling other wavelengths of light besides infrared radiation (with the term “light” encompassing any electromagnetic radiation, including, but not limited to, visible radiation).

The radiation conduits 104, 106, 108, 110, 112, 114, 116 and 120 are configured to spin with susceptor 12 and substrate 14 in the shown aspect of the invention, and to channel the radiation from a back side of substrate 14 to a stationary receptor 150. The channeled radiation is diagrammatically illustrated in FIG. 6 as arrows extending from the conduits 104, 106, 108, 110, 112, 114 and 116 to the receptor 150.

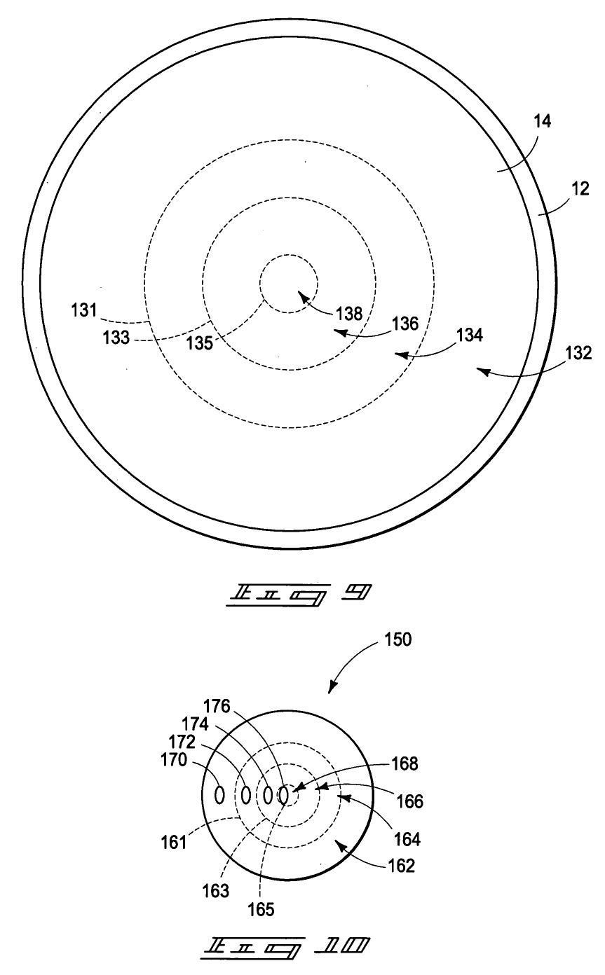

FIG. 8 shows that the receptor 150 comprises a plurality of radiation conduits 152 arranged in concentric rings. Specifically, the array of radiation conduits 152 within the stationary assembly of FIG. 8 is arranged within annular regions 162, 164, 166 and 168 (which are separated by the dashed lines 161, 163 and 165 in FIG. 8). The regions 162, 164, 166 and 168 are in one-to-one correspondence with the regions 122, 124, 126 and 128 of the array of spinning conduits shown in FIG. 7, which in turn are in one-to-one correspondence with the regions 132, 134, 136 and 138 of the semiconductor wafer substrate.

Radiation conduits 152 are in data communication with a detector 154. Specifically, radiation conduits 152 channel radiation received from the spinning conduits 104, 106, 108, 110, 112, 114, 116 and 120 to the detector 154. Seven stationary (i.e., non-rotating) conduits 152 are shown in FIG. 6 to be in one-to-one correspondence with the seven rotating conduits 104, 106, 108, 110, 112, 114 and 116. The conducts 152 can be the same type of fibers as described previously for the conduits 104, 106, 108, 110, 112, 114, 116 and 120, or can be different. The conduits 152 are shown smaller than the conduits 104, 106, 108, 110, 112, 114, 116 and 120 in the diagrammatic drawings of FIGS. 6-8, but it is to be understood that the relative dimensions of the various conduits can be anything suitable. Also, even though all of conduits 152 are shown the same size as one another, it is to be understood that some of the conduits 152 can be different in size from others. Similarly, it is to be understood that some of the conduits 104, 106, 108, 110, 112, 114, 116 and 120 can be different in size than others.

The detector 154 is configured to receive radiation from the conduits 152, and to output one or more data signals 156 in response to radiation (the data signals can be in any suitable form, including, for example, electrical signals). The signals 156 are directed to a signal processor 158 in data communication with the detector 154. The signal processor is configured to process one or more of the signals from the detector 154 and to utilize the signals to ascertain temperatures of the defined regions of the substrate. In preferred aspects of the invention, the temperatures of regions 132, 134, 136 and 138 of the semiconductor wafer substrate are separately analyzed relative to one another. In such aspects, data obtained by conduits in regions 162, 164, 166 and 168 is separately analyzed by detector 154 and signal processor 158 so that the temperatures of regions 132, 134, 136 and 138 of the semiconductor wafer can be separately monitored to assess the uniformity of temperature across the surface of the semiconductor wafer substrate. Since the conduits within susceptor 12 are spinning and the conduits within receptor 150 are not, the information associated with each of annular regions 132, 134, 136 and 138 of the substrate 14 is averaged as the information is passed to the receptor. For instance, information from all of the spinning conduits directly beneath the region 132 of the substrate will be averaged together as the information is passed to stationary receptor 150. Similarly, information from all of the spinning conduits directly beneath the region 134 of the substrate will be averaged as the information is passed to receptor 150; information from all of the spinning conduits directly beneath the region 136 of the substrate will be averaged as the information is passed to receptor 150; and information from all of the spinning conduits directly beneath the region 138 of the substrate will be averaged as the information is passed to receptor 150.

The aspects of the invention described with reference to FIGS. 6-9 are exemplary aspects, and it is to be understood that the invention encompasses other aspects which are not specifically shown. For instance, even though the semiconductor wafer is shown divided into four regions, it is to be understood that the wafer can be divided into less than four or more than four regions, but generally would be divided into at least two separate regions. Also, although the conduits 104, 106, 108, 110, 112, 114 and 116 are shown extending through susceptor 12 in the diagram of FIG. 7, it is to be understood that the invention can encompass other aspects in which the conduits do not extend through the susceptor, such as, for example, aspects in which the susceptor comprises a window through which radiation can pass to conduits located beneath the susceptor. In applications in which the conduits do not pass through the susceptor, it may be desired that none of the conduits spin with the susceptor.

Although the invention was described above as comprising two sets of conduits, with one of the sets being a spinning set of conduits and the other of the sets being a non-spinning conduit, it is to be understood that the shown invention can also be described as comprising a single set of conduits which contains spinning components within the housing 102, and non-spinning (i.e., stationary) components extending from the receptor 150 to the detector 154.

Although the components are shown detecting radiation emitted from a back side of wafer 14, it is to be understood that the invention encompasses other aspects (not shown) in which at least some of the conduits detect radiation emitting from a front side of the semiconductor wafer.

Although the invention can advantageously monitor the temperature while a semiconductor substrate is spinning, it is to be understood that the invention can also be utilized for monitoring temperature while the semiconductor substrate is not spinning, if such is desired.

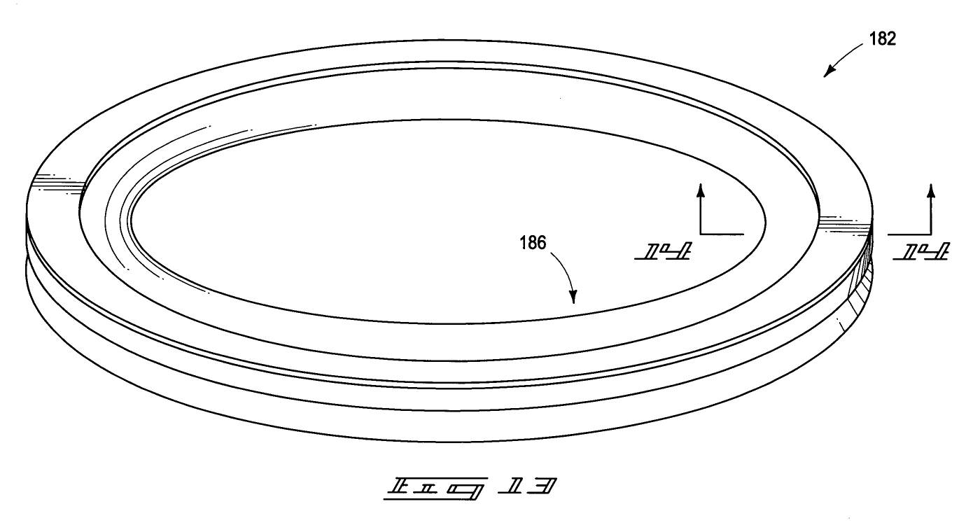

Although the stationary receptor 150 of FIG. 8 has a one-to-one correspondence of conduits with the spinning conduits contained within housing 102 of FIG. 7, it is to be understood that the invention encompasses other aspects in which there is not a one-to-one correspondence between the conduits in the stationary receptor and the spinning conduits. An example of such aspect is shown in FIG. 10. Specifically, FIG. 10 shows a stationary receptor 150 according to a different aspect of the invention than that shown in FIG. 8, with the FIG. 10 stationary receptor comprising only four radiation conduits 170, 172, 174 and 176, rather than the large number of conduits shown in receptor 150 of FIG. 8. The four conduits 170, 172, 174 and 176 are shown larger than the conduits of FIG. 8 to diagrammatically indicate that the size of the conduits can vary relative to the sizes shown in FIG. 8. Each of the conduits 170, 172, 174 and 176 is contained within one of the regions 162, 164, 166 and 168 discussed previously. The conduits can have any suitable shape, and the conduit openings extending through stationary receptor 150 can be circular, elliptical, trough-like, funnel-like etc. in various aspects of the invention.

The embodiments described with reference to FIGS. 6-10 can, in some aspects, be considered to provide optical rotary couplings on a susceptor support which are used to transmit radiant energy signals from a wafer surface (specifically a back side wafer surface in the shown aspects of the invention) to a measurement device. Particular aspects of the invention can utilize radiation conduits extending within a susceptor support shaft. The invention can be advantageous over prior art methodologies. Prior art methodologies estimate wafer surface temperature through measurement with an optical pyrometer which is used to control wafer temperature through the back side of a susceptor comprising silicon carbide coated graphite. The invention advantageously utilizes optical fibers provided in close proximity to the back of the wafer surface so that an actual wafer temperature can be assessed (for example, measured by correlating the wavelength of radiant energy emitted from the back side of the wafer with a wafer temperature).

The optical fibers utilized in the present invention would generally be utilized in a vacuum environment, and, in some aspects, are rotated to transmit a signal out of the measured device into a non-vacuum atmosphere.

The preferred arrangement of the fibers into a circle around the diameter of a support shaft can allow one or more groups of fibers to be in close proximity to the back of a wafer surface which can give an overall estimation of the total wafer temperature. The fiber group can be the length of the support shaft, and can terminate at the shaft base. The fibers within the support shaft can rotate with the shaft. Another group of fibers can be fixed on the base of the rotation unit and held stationary. The fixed fibers can then be in data communication with a measuring device as shown. Although the measuring device is shown comprising a detector which is separate from a signal processing unit, it is to be understood that the detector and signal processing unit can be combined into a single unit in various aspects of the invention. Also, it is to be understood that the signal processing unit can either be in data communication with an output device, or can comprise an output device, so that the wafer temperature is displayed to an operator. Further, it is to be understood that the signal processing unit can comprise, or be in data communication with, a control unit so that information from the signal processing unit is utilized in feedback to the control unit which controls one or more parameters associated with the heating of the semiconductor wafer to maintain the uniformity of temperature across the wafer within desired tolerances during a deposition process.

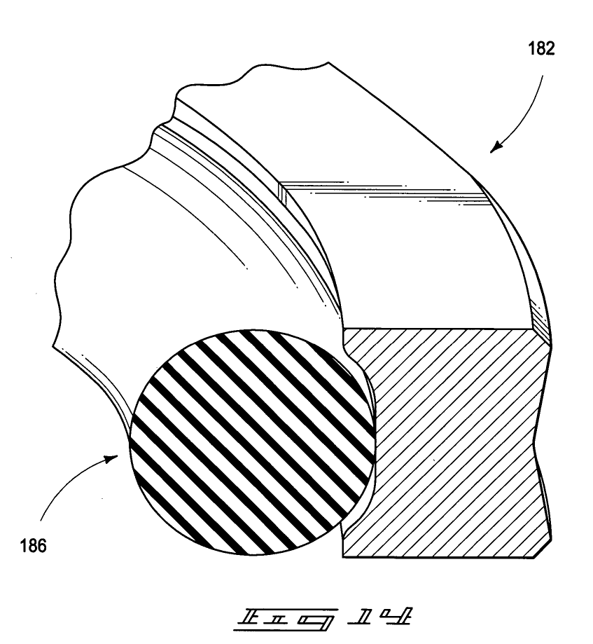

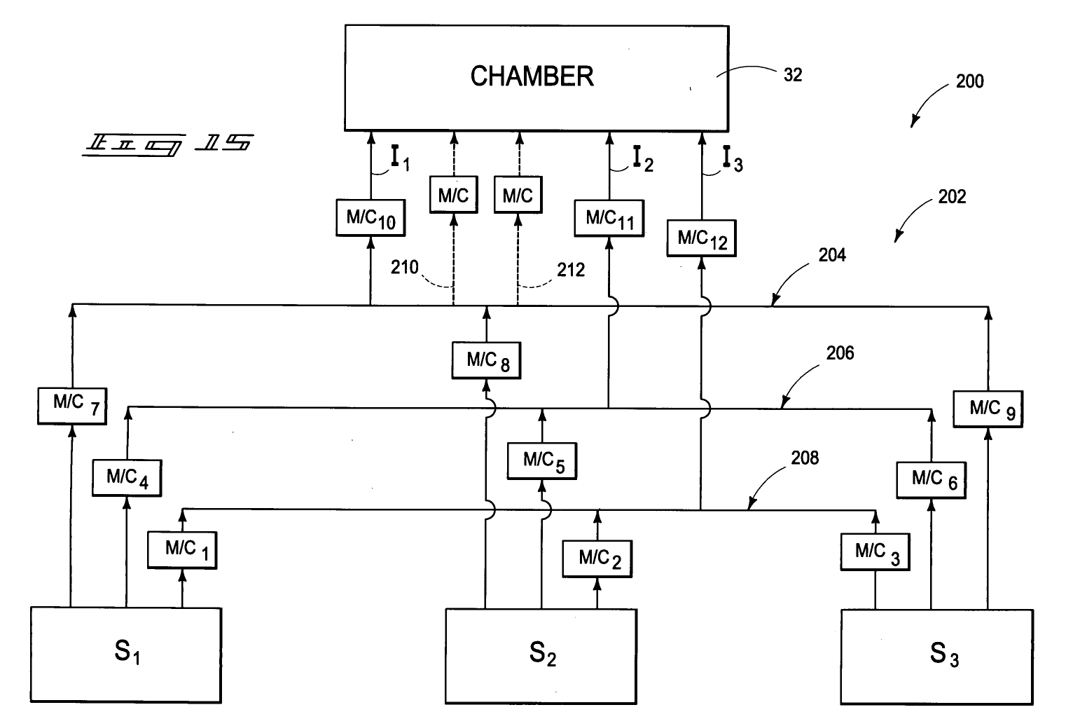

The connection between a rotating shaft having fibers extending therethrough (such as the housing 102 of FIG. 6 with the conduits extending therethrough) and a stationary receptor (such as the receptor 150 of FIG. 6) can be any suitable connection. Preferably the connection will enable vacuum to be maintained within the rotating shaft. Exemplary components that can be utilized for making suitable connections are shown in FIGS. 11-14. FIGS. 11 and 12 show a grooved ring 180 that can be utilized as a coupling member of either the stationary or spinning component, with the other of the stationary or spinning component having an extension which fits within one or more grooves of the grooved ring. FIGS. 13 and 14 show a ring 182 which is yet another embodiment of a grooved ring that can be utilized as a coupling member of either the stationary or spinning component, and show a sealing member 186 retained within the ring. The sealing member 186 can be an O-ring or other gasket member, and can comprise any suitable composition. The grooved rings 180 and 182 of FIGS. 11-14 can comprise any suitable materials, including, for example, metallic materials or ceramic materials.

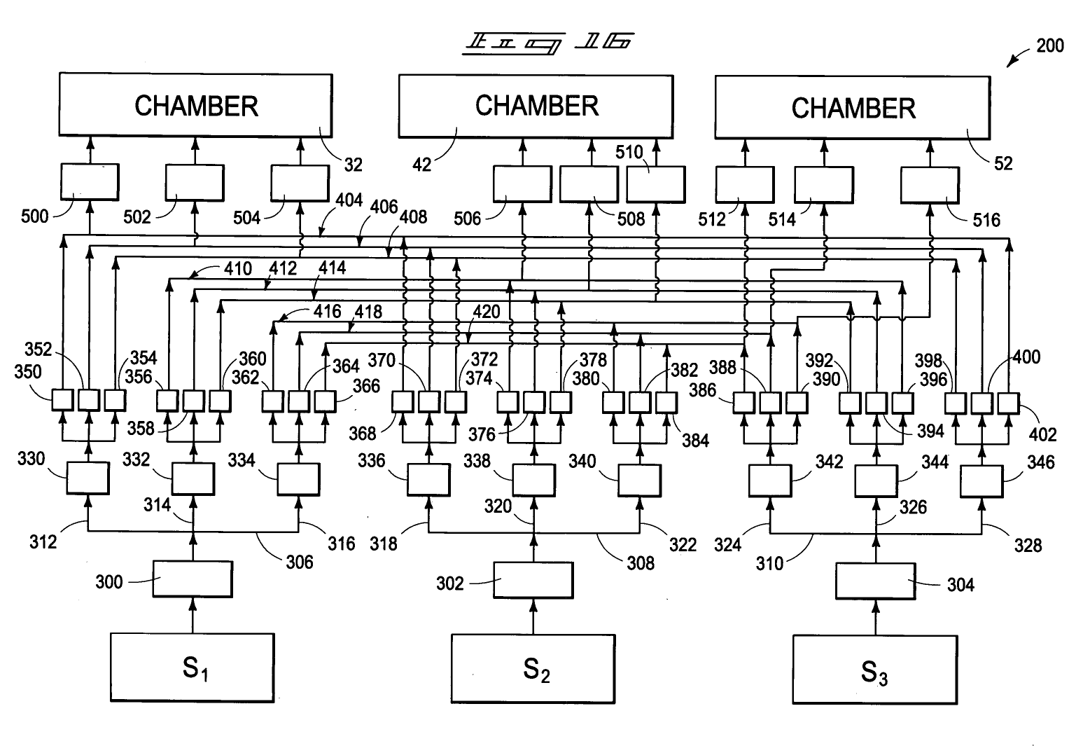

The aspects of the invention described above with reference to FIGS. 6-14 pertain to measurement of the temperature across a semiconductor wafer during a deposition process. Another aspect of the invention pertains to control of the flow of input gases to a reaction chamber during a deposition process. FIGS. 15-17 diagrammatically illustrate improved methods for controlling flow of gases within reaction apparatuses that can be incorporated into deposition processes in accordance with exemplary aspects of the present invention.

Referring first to FIG. 15, such shows an apparatus 200 comprising a reaction chamber, and comprising three gas sources (S₁, S₂ and S₃). The three gas sources can comprise a first gas, a second gas and a third gas, respectively, with the three gases being different from one another. Although the apparatus is shown utilizing three gas sources, it is to be understood that methodology of the present invention can be utilized in apparatuses comprising only two gas sources, or comprising more than three gas sources. The apparatus of FIG. 15 can be utilized for epitaxially growing a semiconductor material over a semiconductor wafer substrate. The material which is epitaxially grown can comprise, consist essentially of, or consist of one or both of silicon and germanium, and in some aspects can comprise, consist essentially of, or consist of doped silicon, doped germanium, or doped silicon/germanium. If the deposited material is to be doped silicon, one of the gases utilized in apparatus 200 can be dichlorosilane, another of the gases can be diatomic hydrogen (H₂), and another of the gases can be a suitable dopant or dopant precursor.

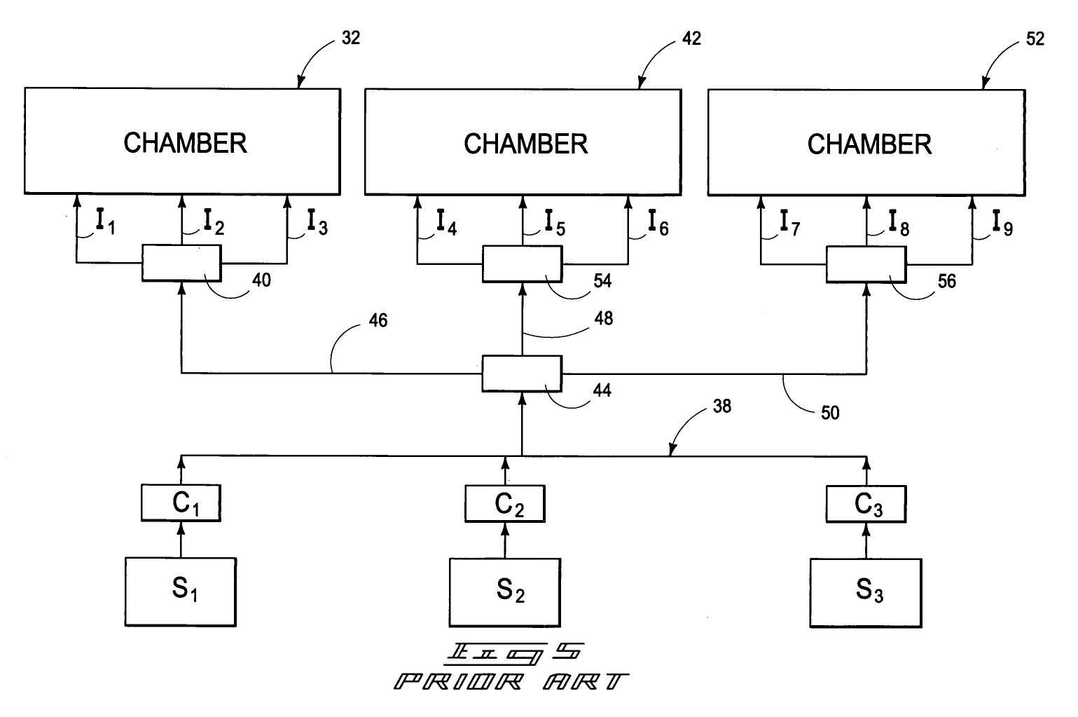

The apparatus 200 of FIG. 15 can be similar to the apparatus described with reference to FIGS. 3-5, and similar features between the apparatus 200 and the apparatus of FIGS. 3-5 are numbered with identical numbers. Accordingly, apparatus 200 is shown to comprise a chamber 32 having inlets I₁, I₂ and I₃ extending therein. It is to be understood that even though three inlets are shown, a chamber can have less than three inlets or more than three inlets in various aspects of the invention. In describing apparatus 200, it is noted that the flow of materials is from the sources to the chamber, and accordingly the flow is defined to be downstream from the sources to the chamber.

The apparatus 200 of FIG. 15 differs from the apparatus of FIGS. 3-5 in that apparatus 200 comprises a flow line system 202 comprising numerous more points of mass flow control and/or mass flow measurement than were present in the flow line system of the prior art apparatus.

The flow line system 202 feeds first, second and third gases from sources S₁, S₂ and S₃ to three separate locations 204, 206 and 208 where the gases are mixed. The mixture from location 204 is fed to inlet I₁, the mixture from location 206 is fed to inlet I₂, and the mixture from location 208 is fed to inlet I₃.

Utilization of a different mixture for each of the inlets can enable control of a deposition process beyond that enabled by the prior art. Specifically, each of the inlets can have a different mixture of gases to compensate for differences in other operational aspects within the chamber (such as, for example, temperature) so that desired uniformity of deposition is maintained across a semiconductor wafer substrate. The composition of the various mixtures going into the different inlets is one of the parameters that can be controlled by feedback from the signal processor 158 of FIG. 6.

The gases flowed from sources S₁, S₂ and S₃ to location 208 are flowed through one or both of a mass flow measurement device and a mass flow controller, with the boxes M/C₁, M/C₂ and M/C₃ designating one or both of a mass flow measurement device and a mass flow controller. The mass flow measuring devices can be separate units from the mass flow controllers in some aspects, and in other aspects at least some of the mass flow measuring devices can be incorporated into units that also comprise mass flow control devices.

The mass flow measurement devices measure mass flow (i.e., gas flow) through the flow lines, and the mass flow controllers control mass flow (i.e., gas flow) through the flow lines. The mass flow measuring devices (also called gas flow meters) measure gas flow but do not control gas flow. The mass flow measuring devices can be utilized to determine the actual flow and/or pressure within a gas line. The measurement of the flow and pressure data can be used for a system setup, and also for process monitoring to determine if a process is in control or moving out of control. The mass flow controllers can be utilized to control the rate of flow within the various lines of the flow system. To the extent that both mass flow measurement devices and mass flow controllers are utilized, the mass flow measurement devices can be upstream of the controllers, downstream of the controllers, or both upstream and downstream of the controllers. The mass flow controllers can be any suitable controllers, including, for example, analog flow controllers available from MKS, STEC, Hitachi, etc. The mass flow measurement devices can also be any suitable devices, including, for example, devices available from MKS.

The source gases flowed to location 206 are, similarly to the source gases flowed to location 208, flowed through mass flow measurement devices and/or mass flow controllers, designated by the boxes M/C₄, M/C₅ and M/C₆; and likewise the gases flowed to location 204 are flowed to mass flow measurement devices and/or mass flow controllers designated by the boxes M/C₇, M/C₈ and M/C₉. Further, the mixed gases flowed to the inlets I₁, I₂ and I₃ are flowed through mass flow measurement devices and/or mass flow controllers, designated by the boxes M/C₁₀, M/C₁₁ and M/C₁₂.

One or more of the shown mass flow measurement devices and/or mass flow controllers can be omitted (i.e., one or more of the boxes M/C₁, M/C₂, M/C₃, M/C₄, M/C₅, M/C₆, M/C₇,M/C₈, M/C₉, M/C₁₀, M/C₁₁ or M/C₁₂ can be omitted), but generally there will be at least one mass flow controller and/or at least one mass flow meter downstream of a location where gases are combined in a flow system of the present invention.

In the aspect of FIG. 15, multiple mass flow controllers and mass flow meters are shown downstream of locations where gases are combined. The utilization of the multiple mass flow meters and/or mass flow controllers can enable significantly better control of a deposition process than is achievable with prior art apparatuses. This can lead to more uniform thicknesses of deposited films formed utilizing methodology of the present invention, and can lead to better homogeneity of deposited compositions formed utilizing processing of the present invention. Additionally, it is frequently desired to selectively deposit materials during semiconductor wafer fabrication. For instance, it is frequently desired to selectively deposit epitaxial semiconductive materials onto specific locations of a semiconductor wafer substrate relative to other locations of the semiconductor wafer substrate. The additional control afforded by methodology of the present invention relative to prior art methodologies can allow selectivities of deposition to be enhanced relative to prior art processes. The multiple mass control and measurement points can also lead to better film growth and predictability utilizing methodology of the present invention relative to the film growth and predictability of prior art processes. Additionally, the various mass control and measurement points associated with the different inlets allows the flow of gas through each inlet to be separately calibrated relative to the others.

Although the flow system 202 shows separate mixing locations (204, 206 and 208) for the gases flowed into each of inlets I₁, I₂ and I₃, it is to be understood that the invention encompasses other aspects wherein a single mixing location is utilized to generate the mixture flowed into inlets I₁, I₂ and I₃, similar to the utilization of the single mixing location 38 and splitter 40 of FIG. 4. Such aspect of the invention is diagrammatically illustrated in FIG. 15 by dashed lines 210 and 212 extending from mixing location 204 to chamber 32. Specifically, a mixture formed at location 204 can be flowed through a splitter, and then flowed into multiple inlets associated with chamber 32, with one of the inlets being I₁ and others of the inlets being at the terminal ends of flow streams 210 and 212.

The flow streams 210 and 212 are shown in dashed line to indicate that such flow streams are optional. If flow streams 210 and 212 are utilized, such can be utilized in place of, or in addition to, the flow streams shown as proceeding to inlets I₂ and I₃.

Each of the flow streams 210 and 212 is shown comprising a mass flow meter and/or mass flow controller. Accordingly, in embodiments in which gases are mixed in a location to form a mixture, and the mixture is then split amongst multiple flow paths which are flowed into a chamber, it is preferred that one or both of a mass flow controller and a mass flow meter be provided on each of the flow paths downstream of the location where the gases are mixed. In the shown aspect of the invention, mass flow meters and/or controllers are provided on all of the flow paths extending from the location where gases are mixed (i.e., are provided on the flow paths 210 and 212, as well as on the flow path going to inlet I₁), but it is to be understood that one or more of the flow paths can be left unregulated by a controller and unmonitored by a mass flow measurement device in some aspects of the invention (not shown).

The various flow controllers of FIG. 15 can be referred to as a first controller, second controller, third controller, etc., in some aspects of the invention; and the various mass flow measurement devices can be referred to as a first mass flow measurement device, second mass flow measurement device, third mass flow measurement device, etc., in various aspects of the invention.

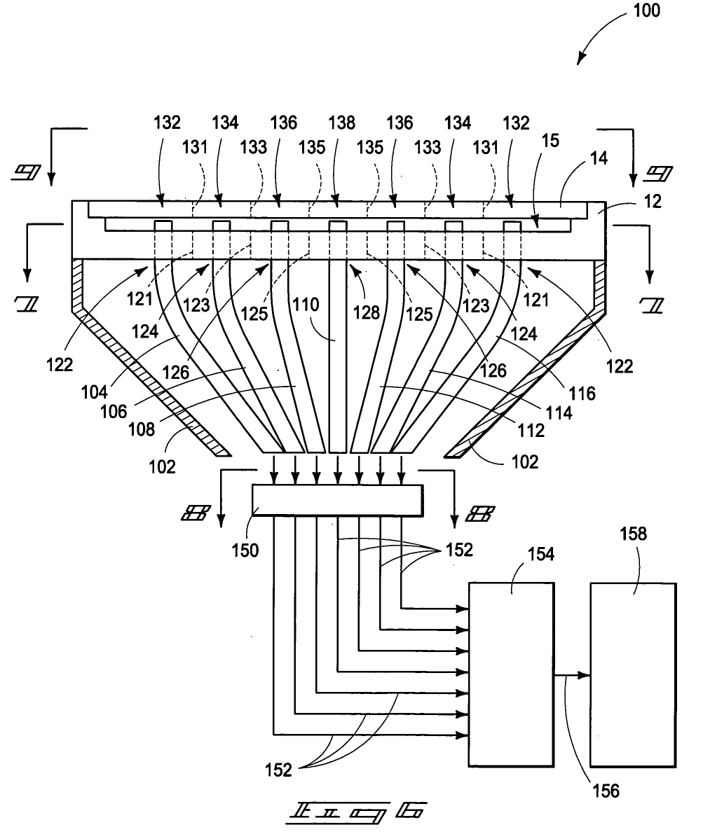

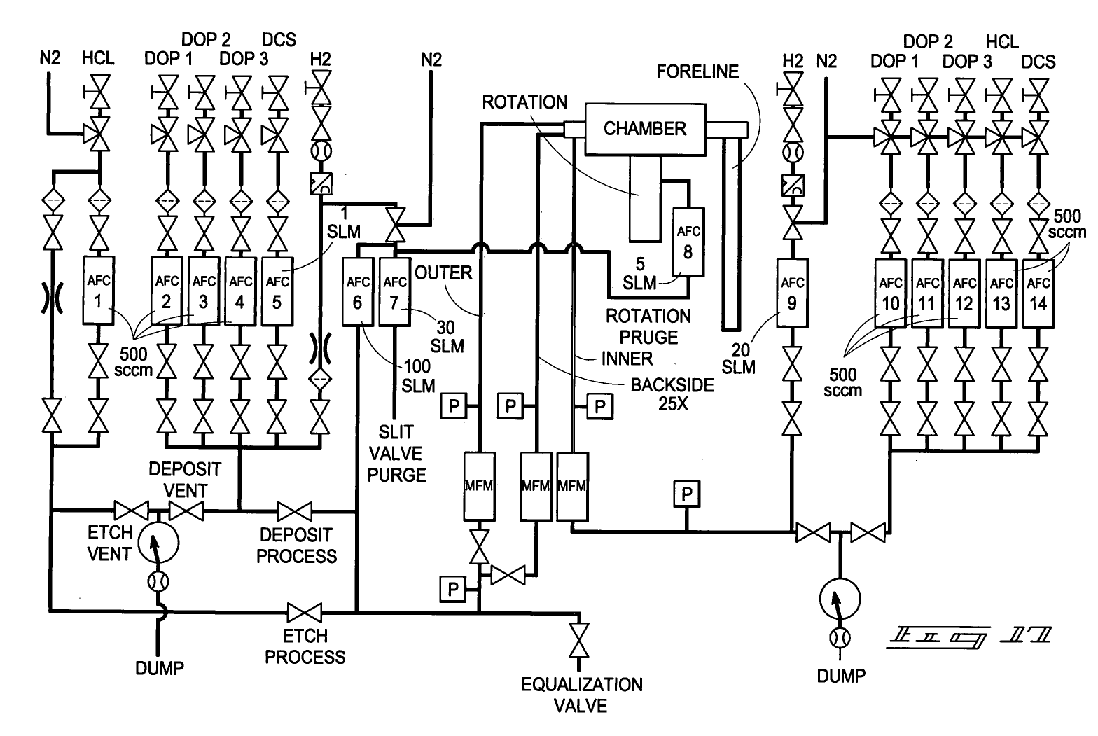

Referring next to FIG. 16, a further aspect of the invention is illustrated. FIG. 16 shows that the flow system of FIG. 15 can be part of a larger flow system in which an apparatus is configured to flow gases to multiple chambers. Specifically, FIG. 16 shows the apparatus 200 of FIG. 15 comprising chambers 42 and 52 in addition to the chamber 32 (with the numbering being identical to that utilized in describing the prior art FIG. 5). Gases from each of the sources flows through one or both of a mass flow meter and mass flow controller (with the mass flow meter/mass flow controller components represented by boxes 300, 302 and 304) to a header 306, 308 or 310 which splits the gas into flow paths associated with each of the chambers 32, 42 and 52.

In the shown aspect of the invention, there are three chambers, and accordingly each of the headers splits the feed gases into three components. The three components flowing from header 306 are labeled as 312, 314 and 316, and such components ultimately flow to the chambers 32, 42 and 52, respectively. Similarly, the three flow paths generated by header 310 are labeled 318, 320 and 322, and such flow paths ultimately lead to chambers 32, 42 and 52 respectively; and the three flow paths generated by header 312 are labeled as 324, 326 and 328, and such flow paths ultimately lead to chambers 32, 42 and 52, respectively.

Each of the flow paths 312, 314, 316, 318, 320, 322, 324, 326 and 328 leads to a mass flow controller and/or meter, as schematically illustrated with boxes 330, 332, 334, 336, 338, 340, 342, 344 and 346 representing mass flow meter devices and/or mass flow controller devices. It is noted that any box designating one or both of a mass flow meter device and a mass flow controller can correspond to a mass flow meter used without a controller, a mass flow controller used without a meter, or systems comprising pluralities of mass flow meters and/or mass flow controllers. If the systems comprise a mass flow controller in combination with one or more mass flow meters, the mass flow meters can be before the controller, after the controller, or both before and after the controller.

The gas flows from the mass flow meter and/or controller systems 330, 332, 334, 336, 338, 340, 342, 344 and 346 each split into multiple flow paths associated with the inlets for the respective chambers. In the shown aspect of the invention, each chamber has three inlets, and accordingly each of the flows from boxes 330, 332, 334, 336, 338, 340, 342, 344 and 346 goes to a header which splits the flow into three components. The three flow paths from box 330 go through mass flow controllers and/or mass flow meters designated by boxes 350, 352 and 354. Similarly, the gas flows through components designated by boxes 332, 334, 336, 338, 340, 342, 344 and 346 proceed through additional components designated by boxes 356, 358, 360, 362, 364, 366, 368, 370, 372, 374, 376, 378, 380, 382, 384, 386, 388, 390, 392, 394, 396, 398, 400, and 402; any of which can comprise one or both of a mass flow controller and a mass flow meter.

The gases flowing through components 350, 368 and 402 are mixed at a location 404, and then the mixture proceeds through one or both of a mass flow controller and mass flow measurement device designated by box 500 to an inlet of chamber 32. Similarly, gases flowed through devices of boxes 352, 370 and 400 are mixed at a location 406, and then passed through mass flow measurement devices and/or mass flow controllers designated by box 502 into chamber 32. Other locations 408, 410, 412, 414,416, 418, and 420 are shown where different gases are combined, and the flow diagram then shows the combined gases going into various inlets associated with chambers 32, 42 and 52. The combined gases are flowed through mass flow controllers and/or mass flow meters designated by boxes 504, 506, 508, 510, 512, 514, and 516 prior to entering inlets of the chambers.

The apparatus of FIG. 16 is similar to the prior art apparatus of FIG. 5, in that the apparatus of FIG. 16 is utilized to flow mixtures of gases to three separate reaction chambers. However, the apparatus of FIG. 16 contains numerous mass flow control points and/or mass flow measurement points lacking from the apparatus of FIG. 5. Such can provide numerous advantages relative to the FIG. 5 apparatus, in that the apparatus of FIG. 16 can enable better operator control of deposition reactions than can be achieved with the apparatus of FIG. 5. This can lead to better uniformity of a thickness of a deposited layer across a semiconductor wafer substrate, better homogeneity of compositions within a deposited layer formed over a semiconductor wafer substrate, and better control of selectivity for depositions which are intended to be selective. Also, in addition to enabling better control within a reaction chamber, the various control points provided in the apparatus of FIG. 16 can enable better control of reaction conditions between reaction chambers which can lead to higher throughput, and better uniformity of wafers processed in different chambers relative to one another than is achieved with the prior art apparatus of FIG. 5.

The apparatus of FIG. 16 has numerous differences relative to the apparatus of FIG. 5, but among the more notable differences are that mass flow controllers and/or mass flow metering devices are provided upstream of the headers 306, 308 and 310 (with such devices being designated by the boxes 300, 302 and 304). Utilization of a control point upstream of a header which splits gas flow amongst different chambers can be particularly advantageous for gases having high flow, such as, for example, for hydrogen (H₂) in deposition of layers comprising epitaxial semiconductor material. Another difference between the apparatus of FIG. 16 and the prior art apparatus of FIG. 5 is that the various mass flow control points and mass flow measurement points of the FIG. 16 apparatus can allow gas flow into each of the chambers 32, 42 and 52 to be separately calibrated relative to the gas flow into the other chambers.

One of the problems with prior art devices is that it can be difficult to transfer recipes from one facility utilizing a particular device to another facility utilizing the same model of the device. It is difficult to get the flow rate throughout the various parts of the flow system to match so that a recipe from one location utilizing one system will be reproducible in another location utilizing a different system. The numerous control points provided in the apparatus of FIG. 16 make it easier to quantitate and control the various flows of gases through the system. Such can make it easier to reproduce a procedure utilized in one apparatus having the features of FIG. 16 within another apparatus having the same features, relative to prior art apparatuses.

Although the systems of FIGS. 15 and 16 show the same three source gases utilized for flowing throughout the various systems, it is to be understood that separate source gases could be used for each of the flow paths throughout the systems. For instance, the source S₁ is shown utilized as a source of a first gas along all of the flow paths 312, 314 and 316 exiting from header 306. In other aspects of the invention, the header 306 can be omitted and three sources of the first gas can be utilized, with each source being separately directed along the flow path 312, 314 or 316. Generally it is most convenient to reduce the number of gas sources utilized within an apparatus, and accordingly the diagrams of FIGS. 15 and 16 can be preferred aspects of the invention relative to flow diagrams utilizing multiple sources of the same gas.

FIG. 17 shows a schematic flow diagram of another apparatus that can be utilized in aspects of the present invention. In referring to FIG. 17, the abbreviation N2 stands for N₂, HCL stands for hydrochloric acid, DOP1, DOP2, and DOP3 are a first dopant, second dopant and third dopant respectively; DCS is dichlorosilane; H2 is H₂; AFC is a mass flow controller, and specifically is an analog flow controller; and MFM is a mass flow measuring device. The abbreviation sccm has its standard definition of standard cubic centimeters per meter, and the abbreviation SLM has its standard definition of standard liters per minute. The units designated by “P” are pumps.

The illustration of FIG. 17 shows two gas delivery panels utilized to optimize delivery of gas to the surface of a wafer during epitaxial silicon growth. It is to be understood that the apparatuses of FIGS. 15 and 16 can utilize two or more panels, similar to the apparatus of FIG. 17, or can utilize a single panel; and similarly the apparatus of FIG. 17 can be collapsed to a single panel if desired.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A deposition apparatus, comprising:
a substrate susceptor for receiving a semiconductor wafer substrate;
one or more heating sources for providing thermal energy to the substrate;
a radiation detector;
a radiation conduit proximate a region of a substrate received in the substrate susceptor and configured to channel radiation from said region of the substrate to the detector, the detector being configured to receive the radiation from the conduit and output one or more data signals in response to the radiation; and
a signal processor in data communication with the detector and configured to process at least one data signal from the detector and to correlate the data signal with a temperature of said region of the substrate.

2. The apparatus of claim 1 wherein the radiation conduit extends through the susceptor.

3. The apparatus of claim 1 wherein:
the susceptor is configured to receive a substantially circular semiconductor substrate;
the substrate is defined to comprise a plurality of annular regions extending radially inwardly of one another;
a plurality of the radiation conduits are provided, with at least one of the radiation conduits being associated with each of the annular regions; and
the signal processor is utilized to estimate temperatures of each of the annular regions.

4. The apparatus of claim 3 configured to spin the susceptor having the substrate received therein, and wherein:
the heating sources provide thermal energy to the substrate as it is spinning;
the radiation conduits channel radiation from the annular regions of the substrate as the substrate is spinning; and
the signal processor estimates temperatures of the annular regions as the substrate is spinning.

5. The apparatus of claim 4 wherein the conduits comprise first and second conduit components; the first conduit components spinning with the substrate and susceptor, and the second conduit components being stationary relative to the spinning substrate and susceptor and being configured to receive radiation from the first conduit components and channel the radiation to the detector.

6. The apparatus of claim 5 wherein the second conduit components are in one-to-one correspondence with the first conduit components.

7. The apparatus of claim 5 wherein the second conduit components are not in one-to-one correspondence with the first conduit components.

8. The apparatus of claim 5 wherein the first conduit components extend through the susceptor.

9. The apparatus of claim 1 wherein the semiconductor wafer has a front side over which a material is to be deposited and a back side facing the susceptor and in opposing relation to the front side, and wherein the conduit detects radiation from the back side of the semiconductor wafer.

10. The apparatus of claim 1 wherein the radiation is infrared radiation, and wherein the conduit is a fiber.

11. A method of assessing the temperature of a semiconductor wafer substrate within a deposition apparatus, comprising:
providing a deposition apparatus having a substrate susceptor for receiving a semiconductor wafer substrate, having a radiation detector, having a plurality of radiation conduits proximate a substrate received in the substrate susceptor and configured to channel radiation from regions of the substrate to the detector, and having a signal processor in data communication with the detector, wherein the detector is configured to receive the radiation from the conduits and output data signals in response to the radiation, and wherein the signal processor is configured to process at least some of the data signals from the detector and to correlate the data signals with temperatures of the regions of the substrate;
providing a semiconductor wafer substrate received by the susceptor, the substrate being defined to comprise a plurality of annular regions extending radially inwardly of one another;
spinning the substrate and susceptor;
while the substrate and susceptor are spinning:
channeling the radiation from the regions of the substrate through the radiation conduits and to the detector; the detector sending data signals to the signal processor in response to the radiation; and
processing the data signals with the signal processor to assess the temperatures of the regions of the substrate.

12. The method of claim 11 wherein:
the conduits comprise first and second conduit components;
the first conduit components are spun with the substrate and susceptor; and
the second conduit components are stationary relative to the spinning substrate and susceptor and are configured to receive radiation from the first conduit components and channel the radiation to the detector.

13. The method of claim 12 wherein the second conduit components are in one-to-one correspondence with the first conduit components.

14. The method of claim 12 wherein the second conduit components are not in one-to-one correspondence with the first conduit components.

15. The method of claim 12 wherein the first conduit components extend through the susceptor.

16. An apparatus configured for deposition of epitaxial semiconductor material, comprising:
a chamber within which the deposition occurs;
a flow line system configured to combine first and second gasses to form a mixture and to direct the mixture to the chamber, the flow of material within the flow line system being defined to be downstream from a location where the first and second gasses are combined to the chamber; and
at least one of a mass flow controller and a mass flow meter downstream of the location where the first and second gasses are combined, where the mass flow controller is other than a simple valve.

17. The apparatus of claim 16 comprising a mass flow meter downstream of the location where the first and second gasses are combined.

18. The apparatus of claim 16 comprising a mass flow controller downstream of the location where the first and second gasses are combined.

19. The apparatus of claim 18 wherein the mass flow controller is an analogue mass flow controller.

20. The apparatus of claim 16 comprising both a mass flow meter and a mass flow controller downstream of the location where the first and second gasses are combined.

21. The apparatus of claim 16 wherein the first gas comprises dichlorosilane and the second gas comprises H₂.

22. The apparatus of claim 21 further comprising at least one additional gas besides the first and second gasses; said at least one additional gas comprising a dopant or dopant precursor and being combined with the first and second gasses at the location where the first and second gases are combined with one another.

23. An apparatus configured for deposition of epitaxial semiconductor material, comprising:
a chamber within which the deposition occurs;
a first source containing first gas;
a second source containing second gas, the second gas being different from the first gas;
a flow line system configured to direct the first and second gasses from the first and second sources to a location where the first and second gasses are combined to form a mixture, to split the mixture amongst at least two flow paths which flow to the chamber, and to direct the mixture along the at least two flow paths to the chamber, the flow of material within the flow line system being defined to be downstream from the first and second sources to the chamber; and
at least one of a mass flow controller and a mass flow meter downstream of the location where the first and second gasses are combined, where the mass flow controller is other than a simple valve.

24. The apparatus of claim 23 comprising a mass flow meter downstream of the location where the first and second gasses are combined.

25. The apparatus of claim 23 comprising a mass flow controller downstream of the location where the first and second gasses are combined.

26. The apparatus of claim 25 wherein the mass flow controller is an analogue mass flow controller.

27. The apparatus of claim 23 comprising both a mass flow meter and a mass flow controller downstream of the location where the first and second gasses are combined.

28. The apparatus of claim 23 wherein the at least two flow paths which flow to the chamber are a first path and a second path, and comprising a first mass flow meter along the first path and a second mass flow meter along the second path.

29. The apparatus of claim 23 wherein the at least two flow paths which flow to the chamber are a first path and a second path, and comprising a first mass flow controller along the first path and a second mass flow controller along the second path.

30. The apparatus of claim 23 wherein the at least two flow paths which flow to the chamber are a first path and a second path; the apparatus comprising a first mass flow controller and a first mass flow meter along the first path, and comprising a second mass flow controller and a second mass flow meter along the second path.

31. The apparatus of claim 23 wherein the first gas comprises dichlorosilane and the second gas comprises H₂.

32. The apparatus of claim 31 further comprising at least one additional gas besides the first and second gasses; said at least one additional gas comprising a dopant or dopant precursor and being combined with the first and second gasses prior to separating the mixture of the first and second gasses along said at least two flow paths.

33. The apparatus of claim 31 comprising a plurality of the chambers and further comprising:
a first header within the flow line system which splits the first gas into separate channels which separately combine with the second gas to form separate mixtures directed toward separate chambers of the plurality of chambers;
a second header within the flow line system which splits the second gas into separate channels which separately combine with the first gas to form separate mixtures directed toward separate chambers of the plurality of chambers; and
at least one of a mass flow controller and a mass flow meter upstream of the first header, where the mass flow controller is other than a simple valve.

34. The apparatus of claim 33 wherein the first gas is H₂.

35. The apparatus of claim 33 further comprising at least one of a mass flow controller and a mass flow meter upstream of the second header, where the mass flow controller is other than a simple valve.

36. An apparatus configured for deposition of epitaxial semiconductor material, comprising:
a plurality of chambers within which the deposition occurs;
a first source containing first gas;
a second source containing second gas, the second gas being different from the first gas;
a flow line system configured to direct the first and second gasses from the first and second sources to a location where the first and second gasses are combined to form a mixture, to split the mixture amongst at least two flow paths which flow to the chamber, and to direct the mixture along the at least two flow paths to the chamber, the flow of material within the flow line system being defined to be downstream from the first and second sources to the chamber;
a first header within the flow line system which splits the first gas into separate channels which separately combine with the second gas to form separate mixtures directed toward separate chambers of the plurality of chambers;
a second header within the flow line system which splits the second gas into separate channels which separately combine with the first gas to form separate mixtures directed toward separate chambers of the plurality of chambers; and
at least one of a mass flow controller and a mass flow meter upstream of the first header, where the mass flow controller is other than a simple valve.

37. The apparatus of claim 36 wherein the first gas comprises H₂ and the second gas comprises dichlorosilane.

38. The apparatus of claim 37 further comprising at least one additional gas besides the first and second gasses; said at least one additional gas comprising a dopant or dopant precursor and being combined with the first and second gasses prior to separating the mixture of the first and second gasses along said at least two flow paths.

39. A method for deposition of epitaxial semiconductor material, comprising:
providing an apparatus comprising a chamber within which the deposition occurs;
providing a semiconductor wafer substrate within the reaction chamber;
providing a first source containing first gas;
providing a second source containing second gas, the second gas being different from the first gas;
providing a flow line system configured to direct the first and second gasses from the first and second sources to a location where the first and second gasses are combined to form a mixture, to split the mixture amongst at least two flow paths which flow to the chamber, and to direct the mixture along the at least two flow paths to the chamber, the flow of material within the flow line system being defined to be downstream from the first and second sources to the chamber; and
providing at least one of a mass flow controller and a mass flow meter downstream of the location where the first and second gasses are combined, where the mass flow controller is other than a simple valve; and
flowing the first and second gasses through the flow line system; and
utilizing the combined first and second gases to deposit an epitaxial semiconductor material over the substrate within the chamber.

40. The method of claim 39 wherein the deposited epitaxial semiconductor material comprises silicon.

41. The method of claim 39 wherein the deposited epitaxial semiconductor material consists essentially of silicon.

42. The method of claim 39 wherein the deposited epitaxial semiconductor material consists of silicon.

43. The method of claim 39 wherein the deposited epitaxial semiconductor material comprises doped silicon.

44. The method of claim 39 wherein the deposited epitaxial semiconductor material consists essentially of doped silicon.

45. The method of claim 39 wherein the deposited epitaxial semiconductor material consists of doped silicon.

46. The method of claim 39 wherein the deposited epitaxial semiconductor material comprises germanium.

47. The method of claim 39 wherein the deposited epitaxial semiconductor material comprises silicon/germanium.

48. The method of claim 39 wherein the deposited epitaxial semiconductor material consists essentially of silicon/germanium.

49. The method of claim 39 wherein the deposited epitaxial semiconductor material consists of silicon/germanium.
